(19) United States
(12) Patent Application Publication
(10) Pub. No.: US 2026/0150184 A1
(43) Pub. Date: May 28, 2026

(54) SEMICONDUCTOR PACKAGE INCLUDING PRINTED CIRCUIT BOARD

(71) Applicant: Samsung Electronics Co., Ltd., Suwon-si (KR)

(72) Inventor: Hyeongseok Kang, Suwon-si (KR)

(21) Appl. No.: 19/273,277

(22) Filed: Jul. 18, 2025

(30) Foreign Application Priority Data
Nov. 27, 2024 (KR) 10-2024-0172761

(51) Int. Cl. H05K 1/02; H01L 23/00; H01L 23/66; H01L 25/065; H05K 1/11; H05K 1/18; H10B 80/00; H10D 80/30

(52) U.S. Cl. CPC H05K 1/0243; H05K 1/113; H05K 1/181; H10W 44/20; H10W 90/00; H05K 2201/09227; H05K 2201/09481; H05K 2201/10287; H10B 80/00; H10D 80/30; H10W 44/206; H10W 44/255; H10W 90/754

(57) ABSTRACT

A semiconductor package includes a printed circuit board and a semiconductor chip electrically connected to the printed circuit board. The printed circuit board includes a plurality of chip connection pads and a plurality of signal correction patterns spaced apart from the plurality of chip connection pads. The semiconductor chip includes a plurality of chip pads. The printed circuit board further includes thereon a board connection member configured to electrically connect the plurality of chip connection pads to the plurality of signal correction patterns to thereby correct signal characteristics between the plurality of chip pads and the plurality of chip connection pads.

### CROSS-REFERENCE TO RELATED APPLICATION

This application is based on and claims priority under 35 U.S.C. § 119 to Korean Patent Application No. 10-2024-0172761, filed on Nov. 27, 2024, in the Korean Intellectual Property Office, the disclosure of which is incorporated by reference herein in its entirety.

### BACKGROUND

The inventive concept relates to a semiconductor package, and more particularly, to a semiconductor package including a printed circuit board.

Semiconductor chips constituting semiconductor packages may be mounted on printed circuit boards. The semiconductor chips communicate with the printed circuit boards via various signal lines. As degrees of integration of semiconductor chips increase and operating speeds of the semiconductor chips also increase, it becomes very important to adjust signal characteristics between the semiconductor chip and the printed circuit boards.

### SUMMARY

The inventive concept provides a semiconductor package capable of adjusting signal characteristics between a printed circuit board and a semiconductor chip.

According to an aspect of the inventive concept, there is provided a semiconductor package including a printed circuit board and a semiconductor chip electrically connected to the printed circuit board. The printed circuit board includes a plurality of chip connection pads and a plurality of signal correction patterns spaced apart from the plurality of chip connection pads. The semiconductor chip includes a plurality of chip pads. The printed circuit board further includes thereon a board connection member configured to electrically connect the plurality of chip connection pads to the plurality of signal correction patterns to correct signal characteristics between the plurality of chip pads and the plurality of chip connection pads.

According to another aspect of the inventive concept, there is provided a semiconductor package including a printed circuit board including signal correction patterns, a semiconductor chip mounted on the printed circuit board, a first signal line configured to electrically connect a first connection point on the printed circuit board to a second connection point on the semiconductor chip, and a second signal line configured to electrically connect a third connection point on the signal correction patterns to the first connection point on the printed circuit board, the third connection point being spaced apart from the first and second connection points, wherein a second length of the second signal line is greater than a first length of the first signal line to correct signal characteristics of the first signal line.

According to another aspect of the inventive concept, there is provided a semiconductor package including a printed circuit board and a semiconductor chip mounted on the printed circuit board and electrically connected to the printed circuit board via a connection member. The printed circuit board includes a plurality of chip connection pads arranged on a board base, wherein the plurality of chip connection pads include a plurality of low-speed signal chip connection pads and at least one high-speed signal chip connection pad and a signal correction unit spaced apart from the plurality of chip connection pads on the board base, wherein the signal correction unit includes a plurality of signal correction patterns spaced apart from each other. The semiconductor chip includes a plurality of chip pads, wherein the plurality of chip pads include a plurality of low-speed signal chip pads and at least one high-speed signal chip pad.

The connection member includes chip connection members configured to electrically connect the plurality of chip pads to the plurality of chip connection pads. The chip connection members include a plurality of low-speed signal chip connection members configured to electrically connect the plurality of low-speed signal chip pads to the plurality of low-speed signal chip connection pads and a high-speed signal chip connection member configured to connect the at least one high-speed signal chip pad to the at least one high-speed signal chip connection pad. The chip connection members include a board connection member configured to electrically connect the at least one high-speed signal chip connection pad to at least one of the plurality of signal correction patterns.

### BRIEF DESCRIPTION OF THE DRAWINGS

Embodiments will be more clearly understood from the following detailed description taken in conjunction with the accompanying drawings in which:

FIG. 1 is a plan view illustrating a semiconductor package including a printed circuit board according to an example embodiment, and FIG. 2 is a perspective view of the semiconductor package according to an example embodiment;

FIG. 3 is a plan view illustrating in detail connection relationships between a first semiconductor chip and signal correction patterns of the semiconductor package of FIGS. 1 and 2;

FIG. 4 is a plan view illustrating a semiconductor package including a printed circuit board according to an example embodiment;

FIGS. 5 and 6 are block diagrams illustrating signal connection relationships between a first semiconductor chip and chip connection pads and between the chip connection pads and signal correction patterns in a semiconductor package according to an example embodiment;

FIG. 7 is a cross-sectional view of a printed circuit board according to an example embodiment;

FIG. 8 is a plan view of the printed circuit board according to an example embodiment;

FIG. 9 is a flowchart illustrating a method of manufacturing a semiconductor package including a printed circuit board, according to an example embodiment;

FIGS. 10 to 17 are diagrams illustrating the method of manufacturing the semiconductor package including the printed circuit board, according to an example embodiment;

FIG. 18 is a cross-sectional view illustrating a semiconductor package including the printed circuit board according to an example embodiment;

FIG. 19 is a cross-sectional view illustrating a semiconductor package including the printed circuit board according to an example embodiment;

FIGS. 20 and 21 illustrate eye diagrams of signal characteristics of semiconductor packages including printed circuit boards according to a comparative example and an example embodiment, respectively;

FIG. 22 is a block diagram schematically showing a configuration of a semiconductor package according to an example embodiment; and

FIG. 23 is a block diagram schematically showing a configuration of a semiconductor package according to an example embodiment.

### DETAILED DESCRIPTION OF THE EMBODIMENTS

Hereinafter, an embodiment is described in detail with reference to the accompanying drawings. The inventive concept may be made by using only one of embodiments described below or by using a combination of one or more embodiments. Accordingly, the inventive concept should not be construed as being limited to one embodiment.

As used herein, the singular forms include the plural forms as well, unless the context clearly indicates otherwise. In this specification, the drawings are exaggerated to more clearly describe the inventive concept. Like reference characters refer to like elements throughout.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

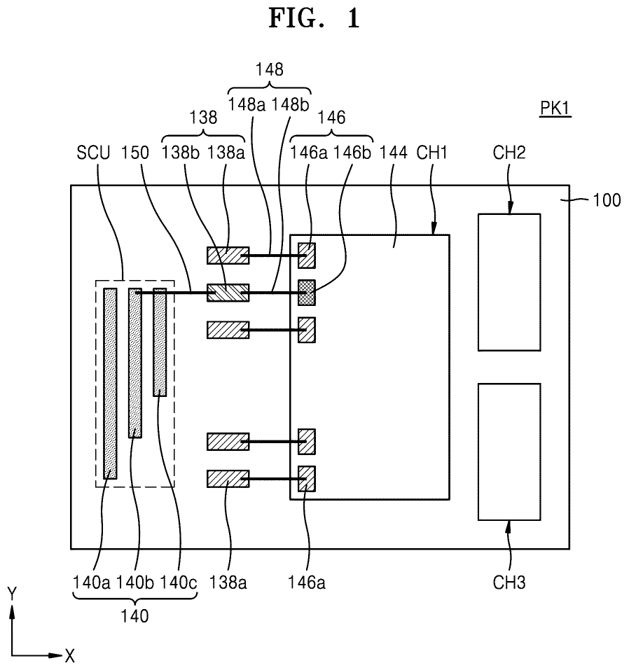

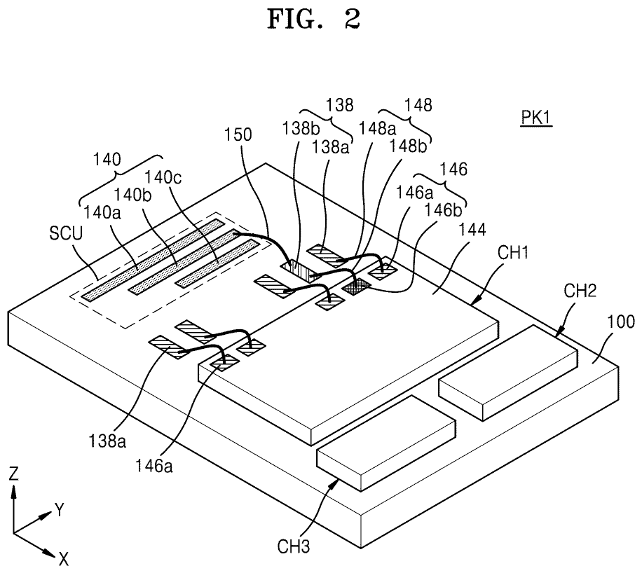

FIG. 1 is a plan view illustrating a semiconductor package PK1 including a printed circuit board 100 according to an example embodiment, and FIG. 2 is a perspective view of the semiconductor package PK1 according to an example embodiment.

Specifically, the semiconductor package PK1 may include a printed circuit board 100 and a plurality of semiconductor chips CH1, CH2, and CH3 (also referred to as first to third semiconductor chips CH1, CH2, and CH3) electrically connected to the printed circuit board 100. The first to third semiconductor chips CH1, CH2, and CH3 may be spaced apart from each other. The first to third semiconductor chips CH1, CH2, and CH3 may include logic chips or memory chips.

The memory chips may include, for example, volatile memory chips, such as dynamic random-access memory (DRAM) and static random-access memory (SRAM) or non-volatile memory chips, such as phase-change RAM (PRAM), magnetoresistive RAM (MRAM), ferroelectric RAM (FeRAM), and resistive RAM (RRAM). The logic chips may also include, for example, a microprocessor, an analog device, a digital signal processor, or an application processor. FIGS. 1 and 2 illustrate three semiconductor chips CH1, CH2, and CH3 for convenience, but the inventive concept is not limited thereto.

In some embodiments, only one semiconductor chip or two semiconductor chips may be mounted on the printed circuit board 100, or three or more semiconductor chips may be mounted on the printed circuit board 100. For convenience, only a connection relationship between the first semiconductor chip CH1 and the printed circuit board 100 is described below in detail.

A plurality of chip pads 146 are arranged on the first semiconductor chip CH1. The chip pads 146 may be located on a chip body 144. The chip pads 146 may include a plurality of low-speed signal chip pads 146a and at least one high-speed signal chip pad 146b.

In the following embodiment, the high-speed signal may represent a signal having a speed of gigabit per second (Gbps). The low-speed signal may represent a signal having a speed of Mbps (megabit per second). In some embodiments, the high-speed signal may represent a signal having an operating frequency greater than or equal to 50 MHz or greater than or equal to 3 GHz, and the low-speed signal may represent a signal having an operating frequency less than 50 MHz.

The printed circuit board 100 may include a plurality of chip connection pads 138 and a plurality of signal correction patterns 140 spaced apart from the chip connection pads 138. The signal correction patterns 140 may include, for example, metal patterns, such as copper patterns. The chip connection pads 138 may also be referred to as chip connection terminals. The chip connection pads 138 may also be referred to as finger patterns or bonding patterns. The chip connection pads 138 may include, for example, metal patterns, such as copper patterns.

The chip connection pads 138 may be on the same plane as the signal correction patterns 140. For example, upper surfaces of the chip connection pads 138 and the signal correction patterns 140 may be coplanar. The chip connection pads 138 may include a plurality of low-speed signal chip connection pads 138a electrically connected to the low-speed signal chip pads 146a and a high-speed signal chip connection pad 138b electrically connected to the high-speed signal chip pad 146b.

The chip connection pads 138 may be electrically connected to the chip pads 146 via chip connection members 148. The chip connection members 148 may include a plurality of low-speed signal chip connection members 148a for electrically connecting the low-speed signal chip pads 146a to the low-speed signal chip connection pads 138a and a high-speed signal chip connection member 148b for connecting the high-speed signal chip pad 146b to the high-speed signal chip connection pad 138b. The chip connection members 148 may include bonding wires.

A board connection member 150 is disposed on the printed circuit board 100 and electrically connects the chip connection pads 138 to at least one of the signal correction patterns 140 to correct the signal characteristics between the chip pads 146 and the chip connection pads 138.

The board connection member 150 may connect the chip connection pads 138 to one end of the signal correction patterns 140. The formation of the board connection member 150 may be performed during a manufacturing process of the semiconductor package PK1, that is, after mounting the first semiconductor chip CH1 on the printed circuit board 100.

In some embodiments, the high-speed signal chip connection pad 138b is electrically connected to a second signal correction pattern 140b, which is at least one of the signal correction patterns 140, via the board connection member 150. In some embodiments, the board connection member 150 may include a bonding wire.

The signal correction patterns 140 may include a first signal correction pattern 140a, the second signal correction pattern 140b, and a third signal correction pattern 140c. The signal correction patterns 140 may constitute a signal correction unit SCU. The signal correction unit SCU may be located on one side of the chip connection pads 138. For example, the chip connection pads 138 may be provided between the signal correction unit SCU and the chip pads 146.

The signal correction patterns 140 may adjust the signal characteristics, such as signal reflection characteristics and signal delay characteristics, between the chip connection pads 138 and the chip pads 146. The signal correction patterns 140 may be pre-formed during the manufacturing process of the printed circuit board 100. FIGS. 1 and 2 illustrate three signal correction patterns 140 for convenience, the inventive concept is not limited thereto.

In some embodiments, the signal correction patterns 140 may be spaced apart from each other and also have different lengths. In some embodiments, the signal correction patterns 140 may be spaced apart from each other and also have different lengths depending on the operating frequency of the first semiconductor chip CH1.

In some embodiments, the first signal correction pattern 140a may have a greater length than the second signal correction pattern 140b and the third signal correction pattern 140c. The second signal correction pattern 140b may have a greater length than the third signal correction pattern 140c. In an example embodiment, the third signal correction pattern 140c may be disposed nearest to the chip connection pads 138, the first signal correction pattern 140a may be disposed furthest away from the chip connection pads 138, and the second signal correction pattern 140b may be disposed between the first signal correction pattern 140a and the third signal correction pattern 140c. One end of the signal correction patterns 140, such as the second signal correction pattern 140b, is electrically connected to the board connection member 150, and the other end of the signal correction patterns 140 is not electrically connected thereto.

In the semiconductor package PK1 as described above, when the signal characteristics, such as signal reflection characteristics and signal delay characteristics, between the high-speed signal chip connection pad 138b of the printed circuit board 100 and the high-speed signal chip pad 146b of the first semiconductor chip CH1 are defective, the length of a signal line is adjusted by electrically connecting the second signal correction pattern 140b to the high-speed signal chip connection pad 138b of the printed circuit board 100 via the board connection member 150.

Accordingly, the semiconductor package PK1 according to the inventive concept may adjust the signal characteristics between the high-speed signal chip connection pad 138b and the high-speed signal chip pad 146b of the first semiconductor chip CH1.

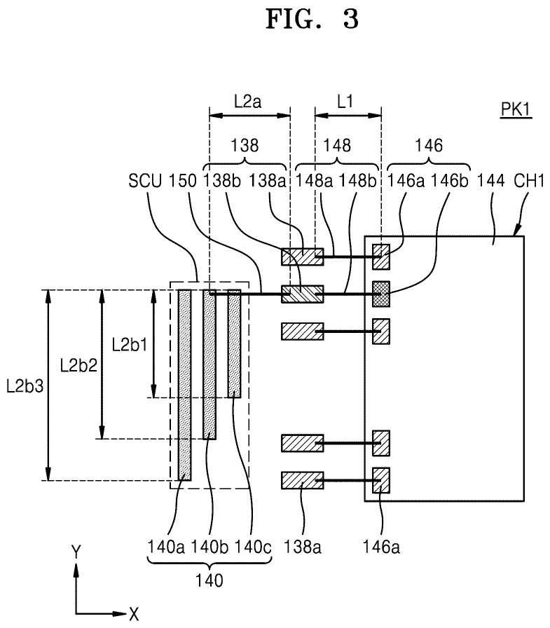

FIG. 3 is a plan view illustrating in detail connection relationships between the first semiconductor chip CH1 and the signal correction patterns 140 of the semiconductor package PK1 of FIGS. 1 and 2.

Specifically, in the description of FIG. 3, the same reference numerals as in FIGS. 1 and 2 indicate the same members. The description above with reference to FIGS. 1 and 2 is briefly given or omitted in the description of FIG. 3.

As described above, the chip connection pads 138 of the semiconductor package PK1 may be electrically connected to the chip pads 146 via the chip connection members 148. The length of the chip connection members 148 between the chip connection pads 138 and the chip pads 146 may have a first length L1.

The high-speed signal chip connection pad 138b is electrically connected to the second signal correction pattern 140b via the board connection member 150. The length of the board connection member 150 in a first horizontal direction (an X direction) between the high-speed signal chip connection pad 138b and the second signal correction pattern 140b may be a first sub-length L2a.

The signal correction patterns 140 may include the first signal correction pattern 140a, the second signal correction pattern 140b, and the third signal correction pattern 140c, which are spaced apart from each other. The third signal correction pattern 140c may have a second sub-length L2b1 in a second horizontal direction (a Y direction). The second signal correction pattern 140b may have a third sub-length L2b2 in the second horizontal direction (the Y direction).

The first signal correction pattern 140a may have a fourth sub-length L2b3 in the second horizontal direction (the Y direction). The fourth sub-length L2b3 may be greater than the second sub-length L2b1 and the third sub-length L2b2. The third sub-length L2b2 may be greater than the second sub-length L2b1.

When the high-speed signal chip connection pad 138b is electrically connected to the second signal correction pattern 140b via the board connection member 150, the total length (L2a+L2b2) of the first sub-length L2a and the third sub-length L2b2 may be greater than the first length L1.

In other words, the semiconductor package PK1 may adjust the length of a signal line between the high-speed signal chip pad 146b and the high-speed signal chip connection pad 138b by using the board connection member 150 and the second signal correction pattern 140b.

Accordingly, the semiconductor package PK1 according to the inventive concept may adjust the signal characteristics, such as signal reflection characteristics and signal delay characteristics, between the high-speed signal chip connection pad 138b and the high-speed signal chip pad 146b of the first semiconductor chip CH1.

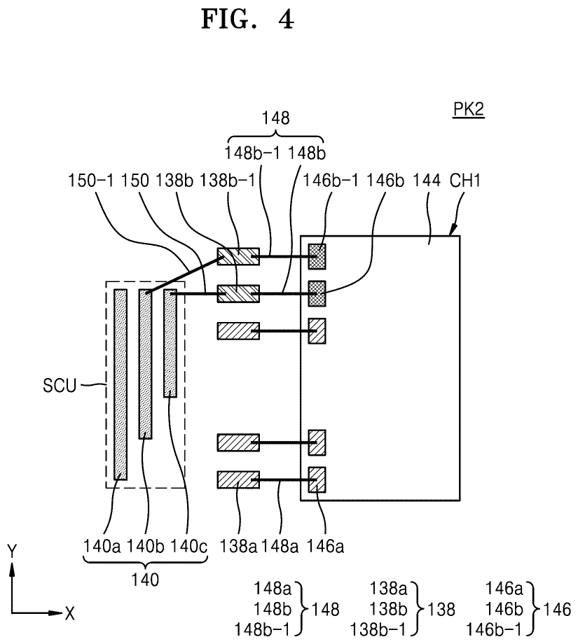

FIG. 4 is a plan view illustrating a semiconductor package PK2 including a printed circuit board according to an example embodiment.

Specifically, FIG. 4 illustrates in detail the connection relationships between the first semiconductor chip CH1 and the signal correction patterns 140. The semiconductor package PK2 may be the same as in FIGS. 1 to 3, except that two of first and second high-speed signal chip pads 146b and 146b-1 are connected to two of a third signal correction pattern 140c and a second signal correction pattern 140b via two of first and second high-speed signal chip connection members 148b and 148b-1 and two of first and second board connection members 150 and 150-1, respectively.

In the description of FIG. 4, the same reference numerals as in FIGS. 1 to 3 indicate the same members. The description above with reference to FIGS. 1 to 3 is briefly given or omitted in the description of FIG. 4. In the semiconductor package PK2, chip pads 146 may be located on a chip body 144 of the first semiconductor chip CH1. The chip pads 146 may include low-speed signal chip pads 146a and the first and second high-speed signal chip pads 146b and 146b-1.

The semiconductor package PK2 may include chip connection pads 138 and signal correction patterns 140 that are arranged on the printed circuit board 100 (FIGS. 1 and 2). The chip connection pads 138 and the signal correction patterns 140 may be arranged on the same plane. For example, upper surfaces of chip connection pads 138 and the signal correction patterns 140 may be coplanar. The chip connection pads 138 may include a low-speed signal chip connection pads 138a and first and second high-speed signal chip connection pads 138b and 138b-1.

On the printed circuit board 100 (FIGS. 1 and 2), the chip connection pads 138 may be electrically connected to the chip pads 146 via the chip connection members 148. The chip connection members 148 may include a low-speed signal chip connection member 148a and the first and second high-speed signal chip connection members 148b and 148b-1.

The signal correction patterns 140 may include a first signal correction pattern 140a, a second signal correction pattern 140b, and a third signal correction pattern 140c. The signal correction patterns 140 may constitute a signal correction unit SCU.

On the printed circuit board 100 (FIGS. 1 and 2), the second signal correction pattern 140b and the third signal correction pattern 140c may be electrically connected to the second high-speed signal chip connection pad 138b-1 and the first high-speed signal chip connection pad 138b, respectively.

In the semiconductor package PK2 as described above, when the signal characteristics, such as signal reflection characteristics and signal delay characteristics, between the first high-speed signal chip connection pad 138b of the printed circuit board 100 (FIGS. 1 and 2) and the first high-speed signal chip pad 146b of the first semiconductor chip CH1 are defective, the length of a signal line is adjusted by electrically connecting the third signal correction pattern 140c to the first high-speed signal chip connection pad 138b of the printed circuit board 100 via the board connection member 150.

Also, in the semiconductor package PK2 as described above, when the signal characteristics, such as signal reflection characteristics and signal delay characteristics, between the second high-speed signal chip connection pad 138b-1 of the printed circuit board 100 (FIGS. 1 and 2) and the second high-speed signal chip pad 146b-1 of the first semiconductor chip CH1 are defective, the length of a signal line is adjusted by electrically connecting the second signal correction pattern 140b to the second high-speed signal chip connection pad 138b-1 of the printed circuit board 100 via the second board connection member 150-1.

Therefore, the semiconductor package PK2 according to the inventive concept may adjust the signal characteristics between the first and second high-speed signal chip connection pads 138b and 138b-1 and the first and second high-speed signal chip pads 146b and 146b-1 of the first semiconductor chip CH1.

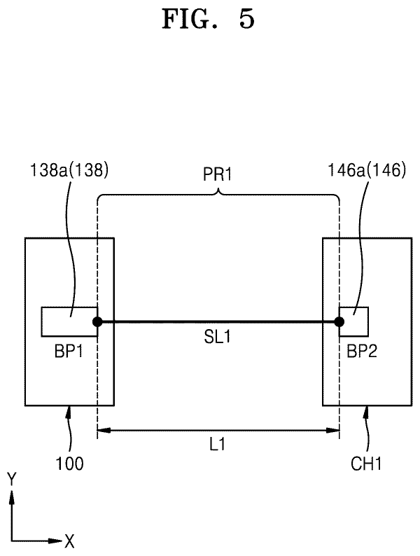

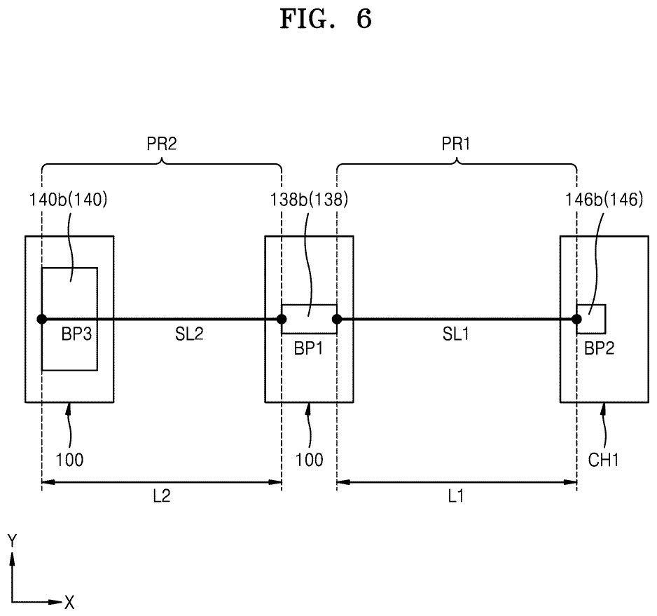

FIGS. 5 and 6 are block diagrams illustrating signal connection relationships between a first semiconductor chip and chip connection pads and between the chip connection pads and signal correction patterns in a semiconductor package according to an example embodiment.

Specifically, FIGS. 5 and 6 illustrate in detail the signal connection relationships between the first semiconductor chip CH1 and the chip connection pads 138 and between the chip connection pads 138 and the signal correction patterns 140 in the semiconductor package PK1 of FIGS. 1 to 3. In the description of FIGS. 5 and 6, the same reference numerals as in FIGS. 1 to 3 indicate the same members.

Referring to FIG. 5, the first semiconductor chip CH1 may be connected to the printed circuit board 100 via a first signal line SL1. The chip pads 146 of the first semiconductor chip CH1 may be connected to the chip connection pads 138 of the printed circuit board 100 via the first signal line SL1. The first signal line SL1 may represent a first signal section PR1 in which signals are transmitted between the first semiconductor chip CH1 and the printed circuit board 100.

The first signal line SL1 may be configured to establish an electrical connection between a first connection point BP1 on the printed circuit board 100 and a second connection point BP2 on the first semiconductor chip CH1. The first connection point BP1 may be located on the chip connection pads 138. For example, the first connection point BP1 may be the point of contact between the first signal line SL1 and one of the chip connection pads 138.

The first connection point BP1 may be located on the low-speed signal chip connection pads 138a. The second connection point BP2 may be located on the chip pads 146. For example, the second connection point BP2 may be the point of contact between the first signal line SL1 and one of the chip pads 146. The first signal line SL1 may include the chip connection members 148 (FIGS. 1 to 3) connecting the chip connection pads 138 to the chip pads 146. The first signal line SL1 may have a first length L1. The first length L1 may represent the length of the chip connection members 148 as described with reference to FIG. 3.

Referring to FIG. 6, the chip connection pads 138 of the printed circuit board 100 may be electrically connected to the signal correction patterns 140 of the printed circuit board 100 via a second signal line SL2.

The second signal line SL2 may represent a second signal section PR2 in which signals are transmitted between the chip connection pads 138 of the printed circuit board 100 and the signal correction patterns 140 of the printed circuit board 100. The first signal line SL1 and the second signal line SL2 may include data signals or control signals.

The second signal line SL2 may be configured to establish an electrical connection between a first connection point BP1 on the printed circuit board 100 and a third connection point BP3 on the printed circuit board 100. The third connection point BP3 may be spaced apart from the first connection point BP1 and a second connection point BP2.

The third connection point BP3 may be located close to the first connection point BP1. The third connection point BP3 may be located on the signal correction patterns 140. For example, the third connection point BP3 may be the point of contact between the second signal line SL2 and the signal correction pattern 140.

The second signal line SL2 may include the board connection member 150 (FIGS. 1 to 3) connecting the chip connection pads 138 to the signal correction patterns 140. The second signal line SL2 may include the board connection member 150 (FIGS. 1 to 3) connecting the high-speed signal chip connection pads 138b to the second signal correction pattern 140b.

The second signal line SL2 may include the board connection member 150 (FIGS. 1 to 3) and the signal correction patterns 140. The second signal line SL2 may include the board connection member 150 (FIGS. 1 to 3) and the second signal correction pattern 140b.

The second signal line SL2 may have a second length L2. The second length L2 of the second signal line SL2 may be the total length (L2a+L2b2) of the first sub-length L2a and the third sub-length L2b2 of FIG. 3.

As described above, the semiconductor package PK1 (FIGS. 1 to 3) may further include the second signal line SL2. The second length L2 of the second signal line SL2 may be configured to be greater than the first length L1 of the first signal line SL1 to correct the signal characteristics of the first signal line SL1. The second length L2 may be determined by the length of the signal correction patterns 140. The lengths of the signal correction patterns 140 may be configured to vary according to operating frequencies of the first semiconductor chip CH1.

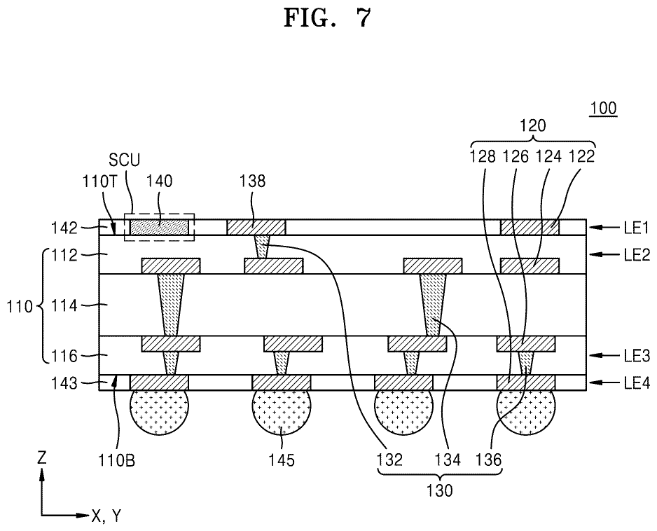

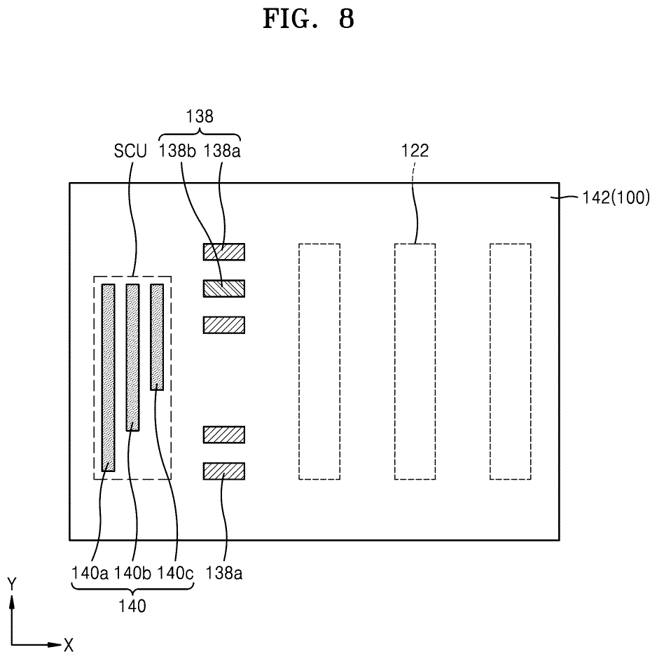

FIG. 7 is a cross-sectional view of a printed circuit board 100 according to an example embodiment, and FIG. 8 is a plan view of the printed circuit board 100 according to an example embodiment.

Specifically, the printed circuit board 100 may include a board base 110 and first to fourth wiring levels LE1, LE2, LE3, and LE4 having a wiring pattern 120. The board base 110 may be formed by stacking a plurality of base layers 112, 114, and 116 (also referred to as first to third base layers 112, 114, and 116).

The first to fourth wiring levels LE1, LE2, LE3, and LE4 may be disposed on upper surfaces and lower surfaces of the plurality of base layers 112, 114, and 116. However, the inventive concept is not limited by the number of base layers and the number of wiring levels in the board base 110.

When the board base 110 is formed by stacking a first base layer 112, a second base layer 114, and a third base layer 116, the first to fourth wiring levels LE1, LE2, LE3, and LE4 may include the first wiring level LE1 on the upper surface of the first base layer 112, the second wiring level LE2 between the lower surface of the first base layer 112 and the upper surface of the second base layer 114, the third wiring level LE3 between the lower surface of the second base layer 114 and the upper surface of the third base layer 116, and the fourth wiring level LE4 on the lower surface of the third base layer 116.

The first to fourth wiring levels LE1, LE2, LE3, and LE4 may have the wiring pattern 120. The first wiring level LE1 may have a first wiring pattern 122, the second wiring level LE2 may have a second wiring pattern 124, the third wiring level LE3 may have a third wiring pattern 126, and the fourth wiring level LE4 may have a fourth wiring pattern 128.

The first to fourth wiring patterns 122, 124, 126, and 128 may each include a conductive material. In some embodiments, the first to fourth wiring patterns 122, 124, 126, and 128 may each include metal. In some embodiments, the first to fourth wiring patterns 122, 124, 126, and 128 provided in the first to fourth wiring levels LE1, LE2, LE3, and LE4, respectively, may include substantially the same metal material.

The first to fourth wiring patterns 122, 124, 126, and 128 may be formed via a plating method. For example, the first to fourth wiring patterns 122, 124, 126, and 128 may include, but not limited to, copper (Cu), nickel (Ni), and/or gold (Au).

A plurality of conductive vias 130 may be formed inside the board base 110 and establish electrical connections between the first to fourth wiring patterns 122, 124, 126, and 128. In some embodiments, the plurality of conductive vias 130 may include copper (Cu), nickel (Ni), and/or beryllium copper.

The plurality of conductive vias 130 may include a first conductive via 132 passing through the first base layer 112, a second conductive via 134 passing through the second base layer 114, and a third conductive via 136 passing through the third base layer 116.

An upper solder resist layer 142 at least partially covering the first wiring pattern 122 may be formed on an upper surface 110T of the board base 110. A lower solder resist layer 143 at least partially covering the fourth wiring pattern 128 may be formed on a lower surface 110B of the board base 110.

A portion of the first wiring pattern 122 may represent the chip connection pads 138 of the printed circuit board 100. The chip connection pads 138 may include the low-speed signal chip connection pads 138a and the high-speed signal chip connection pad 138b. The chip connection pads 138 may be spaced apart from each other as shown in FIG. 8. A portion of the fourth wiring pattern 128 may represent a terminal connection pad of the printed circuit board 100.

The printed circuit board 100 may include the plurality of signal correction patterns 140 that are spaced apart from the chip connection pads 138. The chip connection pads 138 may be on the same plane as the signal correction patterns 140. For example, upper and lower surfaces of the chip connection pads 138 may be coplanar with upper and lower surfaces of the signal correction patterns 140, respectively.

The signal correction patterns 140 may include the first signal correction pattern 140a, the second signal correction pattern 140b, and the third signal correction pattern 140c, as shown in FIG. 8. The signal correction patterns 140 may constitute a signal correction unit SCU. The signal correction unit SCU may be located on one side of the chip connection pads 138.

The first semiconductor chip CH1 (FIGS. 1 to 3) may be mounted on an upper surface of the printed circuit board 100. The upper surface of the printed circuit board 100 may have a chip mounting surface. A solder ball 145, which represents an external connection terminal, may be attached to a lower surface of the printed circuit board 100.

The lower surface of the printed circuit board 100 may have a connection terminal attachment surface. The first wiring pattern 122, representing the chip connection pads 138, may be electrically connected to the first semiconductor chip CH1 (FIGS. 1 to 3). The solder ball 145 may be electrically connected to the fourth wiring pattern 128 that represents a terminal connection pad.

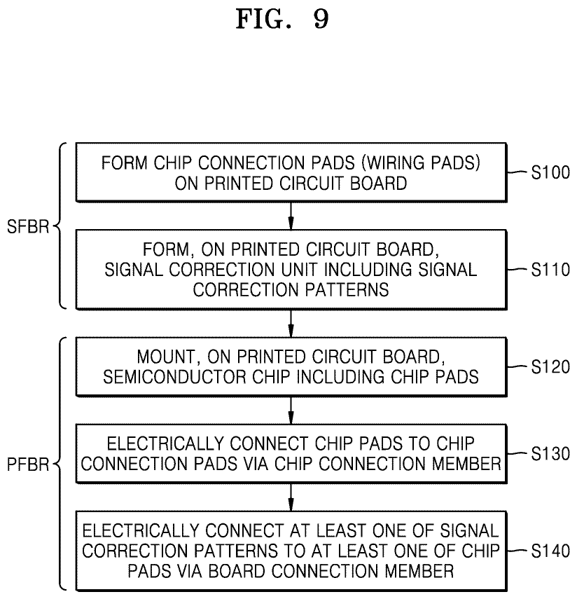

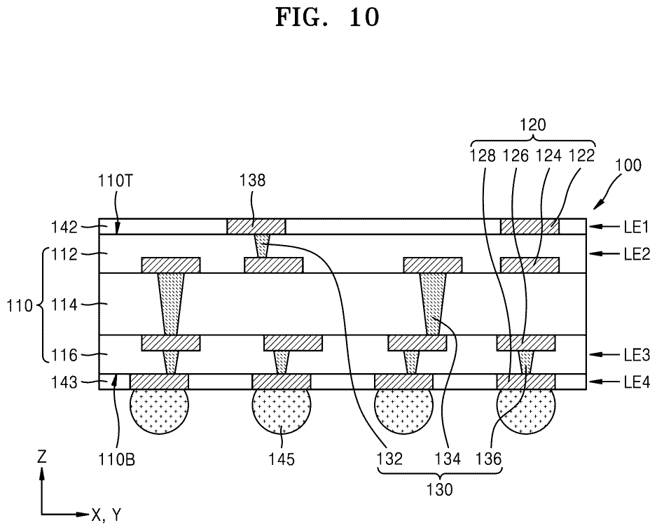

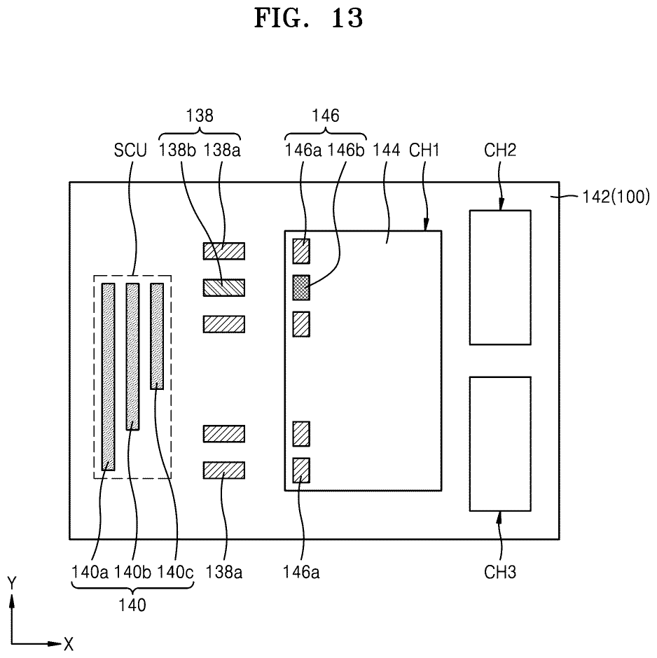

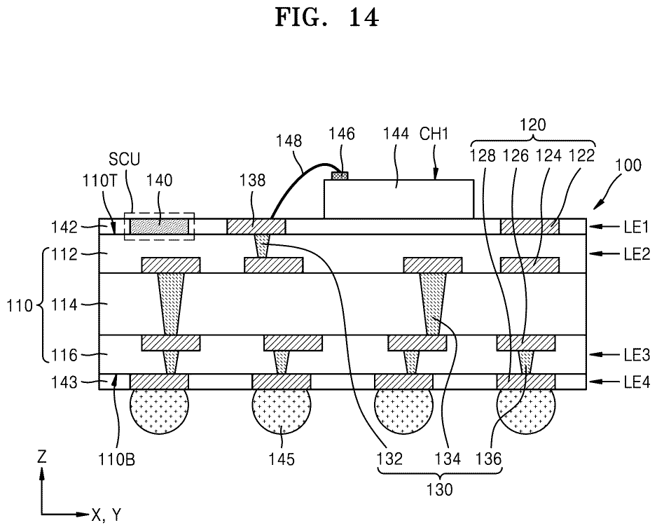

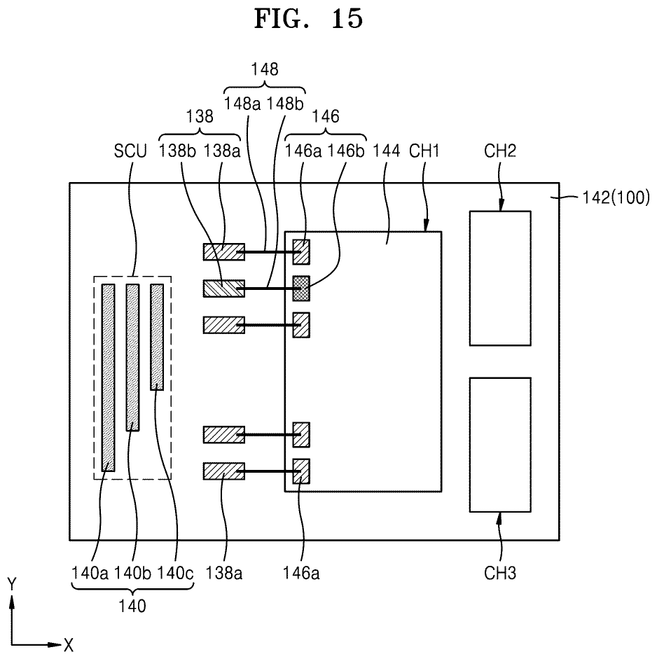

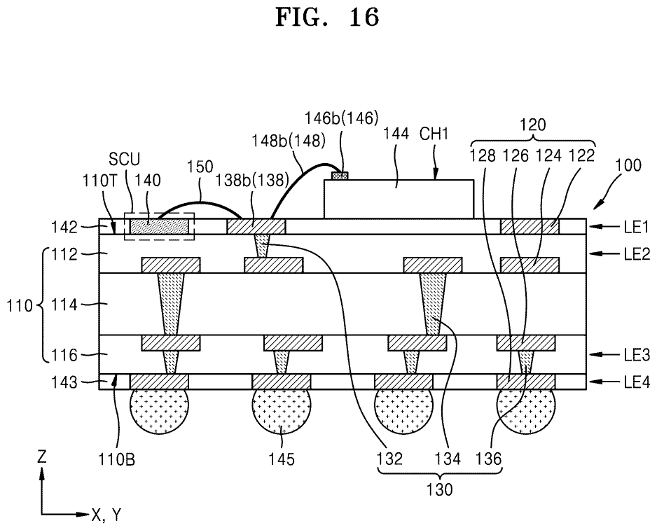

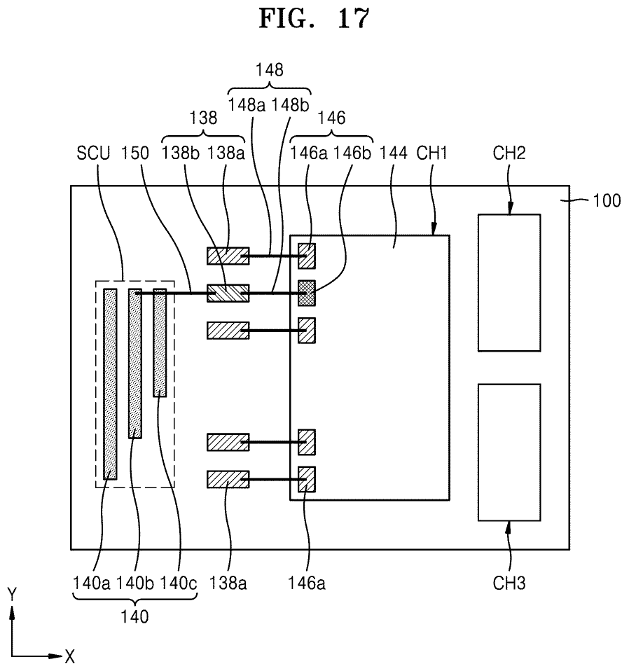

FIG. 9 is a flowchart illustrating a method of manufacturing a semiconductor package including a printed circuit board, according to an example embodiment. Also, FIGS. 10 to 17 are diagrams illustrating the method of manufacturing the semiconductor package including the printed circuit board, according to an example embodiment.

Specifically, FIGS. 9 to 17 illustrate a method of manufacturing the semiconductor package PK1 of FIGS. 1 to 3. FIGS. 9 to 17 may use the printed circuit board 100 of FIGS. 7 and 8.

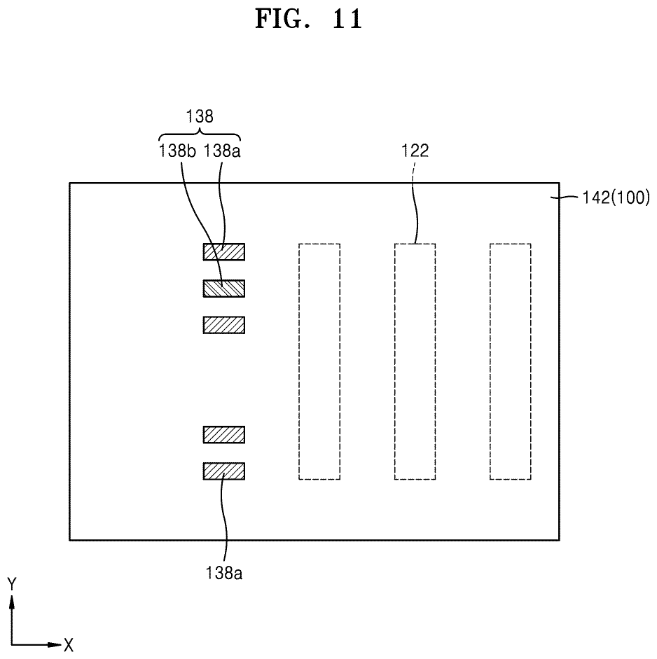

FIGS. 10, 12, 14, and 16 are cross-sectional views illustrating the method of manufacturing the semiconductor package PK1. FIGS. 11, 13, 15, and 17 are plan views illustrating the method of manufacturing the semiconductor package PK1.

In the description of FIGS. 9 to 17, the same reference numerals as in FIGS. 1 to 3, FIG. 7, and FIG. 8 indicate the same members. The description above with reference to FIGS. 1 to 3, FIG. 7, and FIG. 8 is briefly given or omitted in the description of FIGS. 9 to 17.

Referring to FIGS. 9, 10, and 11, the method of manufacturing the semiconductor package PK1 (FIGS. 1 to 3) includes operation S100 of forming chip connection pads (wiring patterns) on the printed circuit board 100.

The printed circuit board 100 may include the board base 110, the first to fourth wiring levels LE1, LE2, LE3, and LE4 having the wiring pattern 120, and the conductive vias 130. The board base 110 may be formed by stacking the plurality of base layers 112, 114, and 116.

The first wiring level LE1 may have the first wiring pattern 122, the second wiring level LE2 may have the second wiring pattern 124, the third wiring level LE3 may have the third wiring pattern 126, and the fourth wiring level LE4 may have the fourth wiring pattern 128. The conductive vias 130 establish electrical connections between the first to fourth wiring patterns 122, 124, 126, and 128 inside the board base 110.

The conductive vias 130 may include the first conductive via 132 passing through the first base layer 112, the second conductive via 134 passing through the second base layer 114, and the third conductive via 136 passing through the third base layer 116.

The printed circuit board 100 includes the upper solder resist layer 142 and the lower solder resist layer 143. The upper solder resist layer 142 may at least partially cover the first wiring pattern 122 on the upper surface 110T of the board base 110. The lower solder resist layer 143 may at least partially cover the fourth wiring pattern 128 on the lower surface 110B of the board base 110.

The printed circuit board 100 includes the chip connection pads 138. The chip connection pads 138 may represent a portion of the first wiring pattern 122. The chip connection pads 138 may be electrically connected to the first wiring pattern 122. The chip connection pads 138 may be referred to as the chip connection terminals. The chip connection pads 138 may also be referred to as the finger patterns or the bonding patterns.

The chip connection pads 138 may be formed on the upper surface 110T of the board base 110. The chip connection pads 138 may be spaced apart from each other. The chip connection pads 138 may include the low-speed signal chip connection pads 138a and the high-speed signal chip connection pad 138b. The printed circuit board 100 may include the solder ball 145. The solder ball 145 may be formed on the lower surface of the printed circuit board 100. The solder ball 145 may represent the external connection terminal.

Referring to FIGS. 9, 12, and 13, the method of manufacturing the semiconductor package PK1 (FIGS. 1 to 3) includes operation S110 of forming a signal correction unit SCU, including signal correction patterns, on the printed circuit board 100.

Operation S100 of forming the chip connection pads (the wiring patterns) on the printed circuit board 100 and operation S110 of forming the signal correction unit, including the signal correction patterns, on the printed circuit board 100 described above may be performed in a printed circuit board 100-manufacturing operation SFBR.

In other words, operation S100 and operation S110 may be performed during the manufacturing process of manufacturing the printed circuit board 100. In particular, operation S110 is performed in advance during the printed circuit board 100-manufacturing operation SFBR so that the signal characteristics are corrected in a package-manufacturing operation PFBR that is performed subsequently. Accordingly, a package manufacturing method according to the inventive concept does not require manufacturing a separate printed circuit board to correct defects in the signal characteristics of the semiconductor package.

The signal correction patterns 140 may be formed on the upper surface 110T of the board base 110. The signal correction patterns 140 may include the first signal correction pattern 140a, the second signal correction pattern 140b, and the third signal correction pattern 140c. The signal correction patterns 140 may constitute the signal correction unit SCU. The signal correction unit SCU may be located on one side of the chip connection pads 138.

In some embodiments, the signal correction patterns 140 may be spaced apart from each other and also have different lengths. In some embodiments, the signal correction patterns 140 may be spaced apart from each other and also have different lengths depending on the operating frequency of the first semiconductor chip CH1.

Next, the method of manufacturing the semiconductor package PK1 (FIGS. 1 to 3) includes operation S120 of mounting semiconductor chips, including chip pads, on the printed circuit board 100.

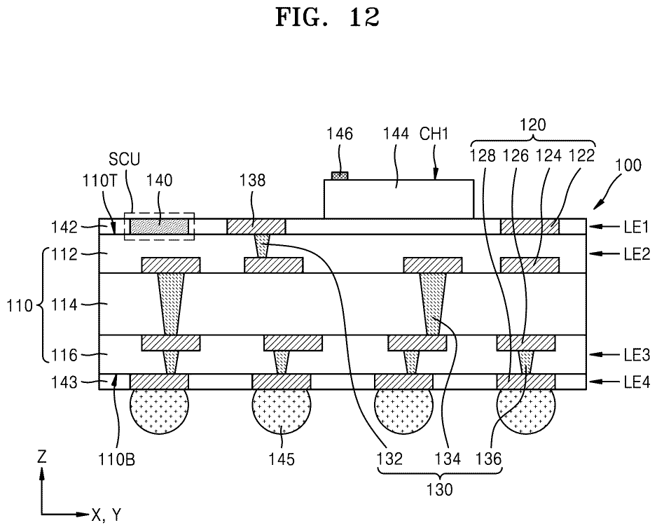

The first to third semiconductor chips CH1, CH2, and CH3 may be arranged on the upper surface of the printed circuit board 100. FIG. 12 illustrates only the first semiconductor chip CH1 for convenience, and the following description focuses on the first semiconductor chip CH1. The first semiconductor chip CH1 may be located on one side of the chip connection pads 138 on the upper surface of the printed circuit board 100.

The plurality of chip pads 146 are arranged on the first semiconductor chip CH1. The chip pads 146 may be located on the chip body 144. The chip pads 146 may be spaced apart from each other. The chip pads 146 may include the plurality of low-speed signal chip pads 146a and the at least one high-speed signal chip pad 146b.

The low-speed signal chip pads 146a may be located adjacent to the low-speed signal chip connection pads 138a arranged on the printed circuit board 100. The high-speed signal chip pad 146b may be located adjacent to the high-speed signal chip connection pad 138b arranged on the printed circuit board 100.

Referring to FIGS. 9, 14, and 15, the method of manufacturing the semiconductor package PK1 (FIGS. 1 to 3) includes operation S130 of electrically connecting chip pads to chip connection pads via a chip connection member.

The chip connection pads 138 may be electrically connected to the chip pads 146 via the chip connection members 148. The chip connection pads 138 may be electrically connected to the chip pads 146 via a wire bonding process. The chip connection members 148 may include bonding wires.

The chip connection members 148 may include the plurality of low-speed signal chip connection members 148a for electrically connecting the low-speed signal chip pads 146a to the low-speed signal chip connection pads 138a and the high-speed signal chip connection member 148b for connecting the high-speed signal chip pad 146b to the high-speed signal chip connection pad 138b.

Referring to FIGS. 9, 16, and 17, the method of manufacturing the semiconductor package PK1 (FIGS. 1 to 3) includes operation S140 of electrically connecting at least one of the signal correction patterns 140 to at least one of chip pads via a board connection member. Operation S120, operation S130, and operation S140 described above are performed in the package-manufacturing operation PFBR.

When the signal characteristics, such as signal reflection characteristics and signal delay characteristics, between the chip pads 146 and the chip connection pads 138 are defective, the chip connection pads 138 are electrically connected to at least one of the signal correction patterns 140 by using the board connection member 150.

Accordingly, the signal characteristics between the chip pads 146 and the chip connection pads 138 are corrected. The chip connection pads 138 may be electrically connected to the signal correction patterns 140 via a wire bonding process. The board connection member 150 may include a bonding wire.

In some embodiments, the high-speed signal chip connection pad 138b is electrically connected to the second signal correction pattern 140b, which is at least one of the signal correction patterns 140, via the board connection member 150.

In the semiconductor package manufacturing method according to the inventive concept, when the signal characteristics between the chip pads 146 and the chip connection pads 138, for example, between the high-speed signal chip pad 146b and the high-speed signal chip connection pad 138b, are defective, the signal characteristics may be corrected by electrically connecting the high-speed signal chip connection pad 138b to the second signal correction pattern 140b via the board connection member 150.

Furthermore, in the semiconductor package manufacturing method according to the inventive concept, the signal correction patterns 140 may be formed in advance on the printed circuit board 100, and thus, the signal correction may be performed in the package-manufacturing operation without manufacturing an additional printed circuit board. Therefore, the manufacturing cost and manufacturing time of the semiconductor package may be significantly reduced.

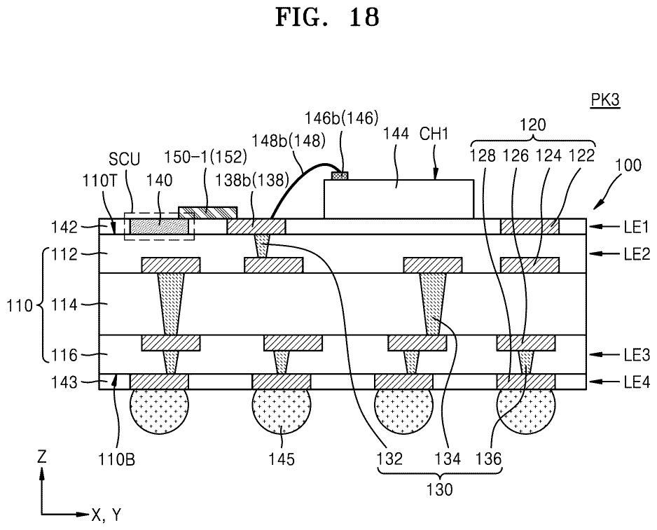

FIG. 18 is a cross-sectional view illustrating a semiconductor package PK3 including the printed circuit board 100 according to an example embodiment.

Specifically, the semiconductor package PK3 may be the same as the semiconductor package PK1 described with reference to FIGS. 1 to 3 and FIGS. 9 to 17, except that a board connection member 150-1 is different from that of the semiconductor package PK1. In the description of FIG. 18, the same reference numerals as in FIGS. 1 to 3 and FIGS. 9 to 17 indicate the same members. The description above with reference to FIGS. 1 to 3 and FIGS. 9 to 17 is briefly given or omitted in the description of FIG. 18.

In the semiconductor package PK3, the first semiconductor chip CH1 is mounted on the printed circuit board 100. The printed circuit board 100 may include the board base 110, the first to fourth wiring levels LE1, LE2, LE3, and LE4 having the wiring pattern 120, and the conductive vias 130. The board base 110 may be formed by stacking the plurality of base layers 112, 114, and 116.

The first to fourth wiring levels LE1, LE2, LE3, and LE4 may have the wiring pattern 120. The wiring pattern 120 includes the first to fourth wiring patterns 122, 124, 126, and 128. The conductive vias 130 may establish electrical connections between the first to fourth wiring patterns 122, 124, 126, and 128. The conductive vias 130 may include the first to third conductive vias 132, 134, and 136.

In the printed circuit board 100, the upper solder resist layer 142 at least partially covering the first wiring pattern 122 may be formed on the upper surface 110T of the board base 110. The lower solder resist layer 143 at least partially covering the fourth wiring pattern 128 may be formed on the lower surface 110B of the board base 110.

A portion of the first wiring pattern 122 may represent the chip connection pads 138 of the printed circuit board 100. The chip connection pads 138 may include the high-speed signal chip connection pad 138b. The first semiconductor chip CH1 (FIGS. 1 to 3) may be mounted on the upper surface of the printed circuit board 100. The solder ball 145, which represents an external connection terminal, may be attached to the lower surface of the printed circuit board 100.

The plurality of chip pads 146 are arranged on the first semiconductor chip CH1. The chip pads 146 may be located on the chip body 144. The chip pads 146 may include the high-speed signal chip pad 146b. The semiconductor package PK3 may include the chip connection members 148.

The chip pads 146 may be electrically connected to the chip connection pads 138 via the chip connection members 148. The chip connection members 148 may include the high-speed signal chip connection member 148b for connecting the high-speed signal chip pad 146b to the high-speed signal chip connection pad 138b. The chip connection members 148 may include bonding wires.

The printed circuit board 100 may include the signal correction patterns 140. The signal correction patterns 140 may constitute the signal correction unit SCU. The semiconductor package PK3 includes the board connection member 150-1. The board connection member 150-1 may electrically connect the chip connection pads 138 to the signal correction patterns 140 on the printed circuit board 100.

The board connection member 150-1 may electrically connect the high-speed signal chip connection pad 138b to the signal correction patterns 140. The board connection member 150-1 may include a board connection pattern 152. The board connection pattern 152 may be formed by a printing method, such as an inkjet printing method.

In the semiconductor package PK3 as described above, the high-speed signal chip connection pad 138b and a signal correction pattern 140 are connected to each other by the board connection member 150-1, i.e., the board connection pattern 152, thereby adjusting the signal characteristics between the chip pads 146 and the chip connection pads 138.

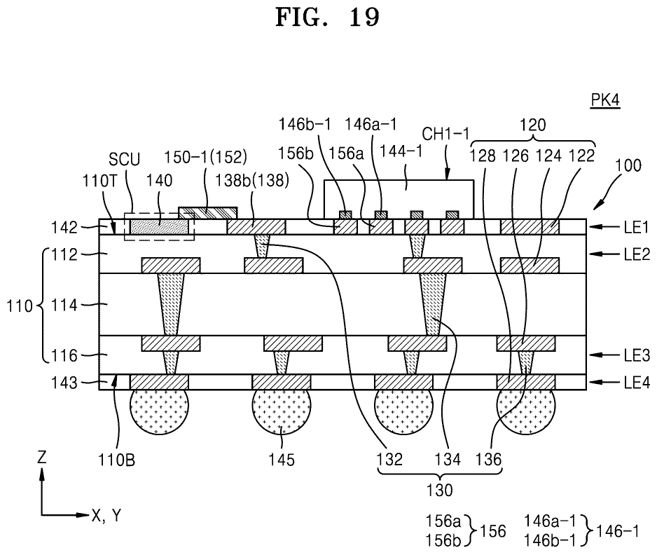

FIG. 19 is a cross-sectional view illustrating a semiconductor package PK4 including the printed circuit board 100 according to an example embodiment.

Specifically, the semiconductor package PK4 may be the same as the semiconductor package PK1 described with reference to FIGS. 1 to 3 and FIGS. 9 to 17, except that a first semiconductor chip 144-1 is flip-chip bonded, and the board connection member 150-1 is different from that of the semiconductor package PK1.

In the description of FIG. 19, the same reference numerals as in FIGS. 1 to 3 and FIGS. 9 to 17 indicate the same members. The description above with reference to FIGS. 1 to 3 and FIGS. 9 to 17 is briefly given or omitted in the description of FIG. 19.

In the semiconductor package PK4, a first semiconductor chip CH1-1 is mounted on the printed circuit board 100. The printed circuit board 100 may include the board base 110, the first to fourth wiring levels LE1, LE2, LE3, and LE4 having the wiring pattern 120, and the conductive vias 130. The board base 110 may be formed by stacking the plurality of base layers 112, 114, and 116.

The first to fourth wiring levels LE1, LE2, LE3, and LE4 may have the wiring pattern 120. The wiring pattern 120 includes the first to fourth wiring patterns 122, 124, 126, and 128. The conductive vias 130 may establish electrical connections between the first to fourth wiring patterns 122, 124, 126, and 128. The conductive vias 130 may include the first to third conductive vias 132, 134, and 136.

In the printed circuit board 100, the upper solder resist layer 142 at least partially covering the first wiring pattern 122 may be formed on the upper surface 110T of the board base 110. The lower solder resist layer 143 at least partially covering the fourth wiring pattern 128 may be formed on the lower surface 110B of the board base 110.

A portion of the first wiring pattern 122 may represent the chip connection pads 138 of the printed circuit board 100. The chip connection pads 138 may include the high-speed signal chip connection pad 138b. A portion of the first wiring pattern 122 may represent chip connection wires 156. The chip connection wires 156 may include a high-speed signal chip connection wire 156b and a low-speed signal chip connection wire 156a. In example embodiments, upper and lower surfaces of the chip connection wires 156 may be coplanar with upper and lower surfaces of the chip connection pads 138, respectively.

The first semiconductor chip CH1-1 may be mounted on the upper surface of the printed circuit board 100. The solder ball 145, which represents an external connection terminal, may be attached to the lower surface of the printed circuit board 100. A plurality of chip pads 146-1 are arranged on a lower surface of the first semiconductor chip CH1-1.

The chip pads 146-1 may be arranged on a lower surface of a chip body 144-1. Lower surfaces of the chip pads 146-1 may be coplanar with the lower surface of the chip body 144-1. The chip pads 146-1 may include a high-speed signal chip pad 146b-1 and a low-speed signal chip pad 146a-1.

The chip pads 146-1 may be respectively flip-chip bonded to the chip connection wires 156. The chip pads 146-1 may be electrically and respectively connected to the chip connection wires 156. The chip pads 146-1 may be electrically and respectively connected to the chip connection pads 138 via the chip connection wires 156.

The printed circuit board 100 may include the signal correction patterns 140. The signal correction patterns 140 may constitute the signal correction unit SCU. The semiconductor package PK4 includes the board connection member 150-1. The board connection member 150-1 may electrically connect the chip connection pads 138 to the signal correction patterns 140 on the printed circuit board 100.

The board connection member 150-1 may electrically connect the high-speed signal chip connection pad 138b to the signal correction pattern 140. The board connection member 150-1 may include the board connection pattern 152. The board connection pattern 152 may be formed by a printing method, such as an inkjet printing method.

In the semiconductor package PK4 as described above, the high-speed signal chip connection pad 138b and the signal correction pattern 140 are connected to each other by the board connection member 150-1, i.e., the board connection pattern 152, thereby adjusting the signal characteristics between the chip pads 146-1 and the chip connection pads 138.

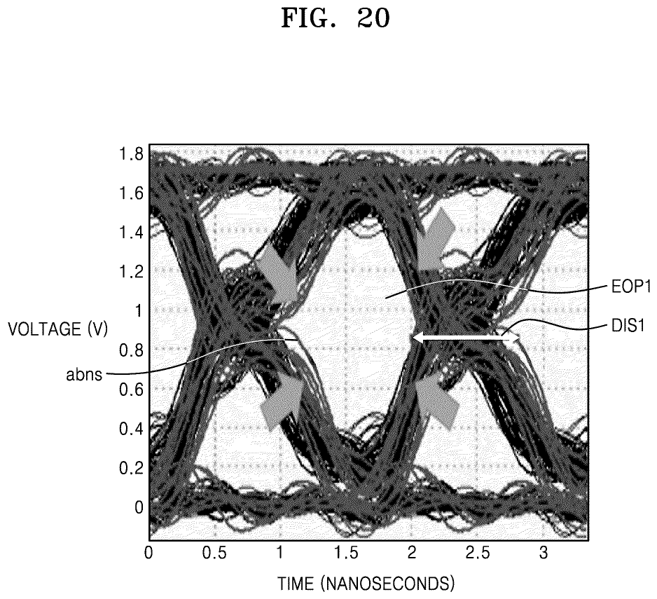

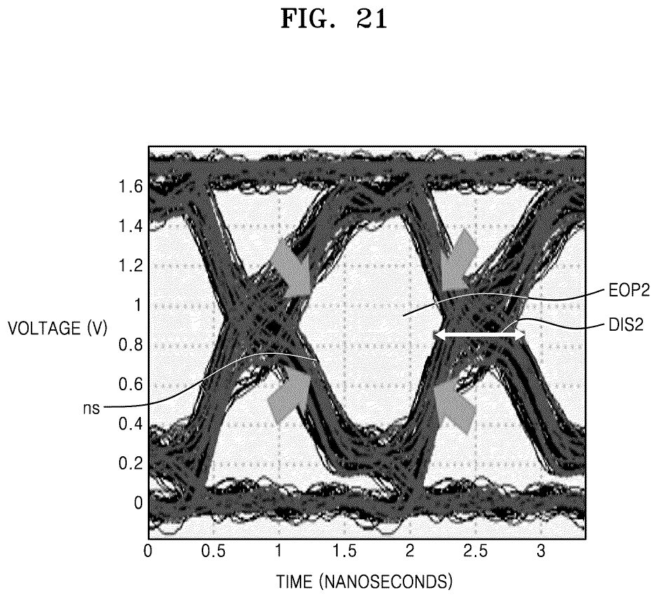

FIGS. 20 and 21 illustrate eye diagrams of signal characteristics of semiconductor packages including printed circuit boards according to a comparative example and an embodiment, respectively.

Specifically, FIG. 20 illustrates the eye diagram of signal characteristics of the semiconductor package according to the comparative example, and FIG. 21 illustrates the eye diagram of signal characteristics of the semiconductor package PK1 according to the embodiments described with reference to FIGS. 1 to 3.

FIG. 20 may illustrate an example of not including the signal correction patterns 140 and the board connection member 150 of FIGS. 1 to 3, and FIG. 21 may illustrate an example of including the signal correction patterns 140 and the board connection member 150.

The semiconductor package according to the comparative example in FIG. 20 shows that an opening width EOP1 of an eye pattern is small, an abnormal signal abns appears, and a width DIS1 at which rising and falling portions of a waveform intersect is large.

In contrast, the semiconductor package according to the inventive concept of FIG. 21 shows that an opening width EOP2 of an eye pattern is large, a normal signal ns appears, and a width DIS2 at which rising and falling portions of a waveform intersect is small. As a result, it can be seen that the semiconductor package according to the inventive concept has signal integrity.

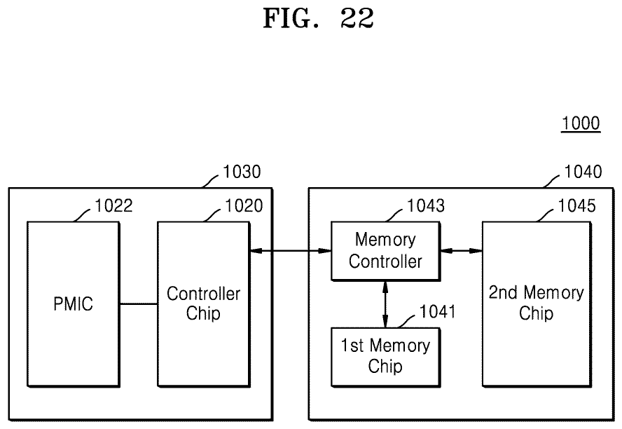

FIG. 22 is a block diagram schematically showing a configuration of a semiconductor package 1000 according to an example embodiment.

Specifically, the semiconductor package 1000 may include any one of the semiconductor packages PK1 to PK4 according to the inventive concept. The semiconductor package 1000 may include a controller chip 1020, a first memory chip 1041, a second memory chip 1045, and a memory controller 1043.

The semiconductor package 1000 may further include a power management integrated circuit (PMIC) 1022 for supplying current of an operating voltage to each of the controller chip 1020, the first memory chip 1041, the second memory chip 1045, and the memory controller 1043. The operating voltages applied to the respective components may be equally or differently designed.

A first semiconductor package 1030 including the controller chip 1020 and the PMIC 1022 may include any one of the semiconductor packages PK1 to PK4 according to the inventive concept described above.

A second semiconductor package 1040 including the first memory chip 1041, the second memory chip 1045, and the memory controller 1043 may include any one of the semiconductor packages PK1 to PK4 according to the inventive concept described above. The second semiconductor package 1040 may be stacked on the first semiconductor package 1030.

The semiconductor package 1000 may be provided in a personal computer (PC) or a mobile device. The mobile device may be formed as a laptop computer, a mobile phone, a smart phone, a tablet PC, a personal digital assistant (PDA), an enterprise digital assistant (EDA), a digital still camera, a digital video camera, a portable multimedia player (PMP), a personal navigation device or portable navigation device (PND), a handheld game console, a mobile internet device (MID), a wearable computer, an internet of things (IoT) device, an internet of everything (IoE) device, or a drone.

The controller chip 1020 may control an operation of each of the first memory chip 1041, the second memory chip 1045, and the memory controller 1043. For example, the controller chip 1020 may be formed as an integrated circuit (IC), a system on chip (SoC), an application processor (AP), a mobile AP, a chip set, or a group of chips.

The controller chip 1020 may include a central processing unit (CPU), a graphics processing unit (GPU), and/or a modem. In some embodiments, the controller chip 1020 may perform a function of the modem and a function of the AP.

The memory controller 1043 may control the second memory chip 1045 under control by the controller chip 1020. The first memory chip 1041 may be formed as a volatile memory device. The volatile memory device may be formed as random-access memory (RAM), dynamic RAM (DRAM), or static RAM (SRAM), but the embodiment is not limited thereto. The second memory chip 1045 may be formed as a storage memory device. The storage memory device may be formed as a non-volatile memory device.

The storage memory device may be formed as a flash-based memory device, but the embodiment is not limited thereto. The second memory chip 1045 may be formed as a NOT-AND (NAND)-type flash memory device. The NAND-type flash memory device may include a 2-dimensional memory cell array or a 3-dimensional memory cell array.

The 2-dimensional memory cell array or the 3-dimensional memory cell array may include a plurality of memory cells, and each of the plurality of memory cells may store 1-bit information or 2-bit or more information.

When the second memory chip 1045 is formed as the flash-based memory device, the memory controller 1043 may use (or support) a multimedia card (MMC) interface, an embedded MMC (eMMC) interface, or a universal flash storage (UFS) interface, but the embodiment is not limited thereto.

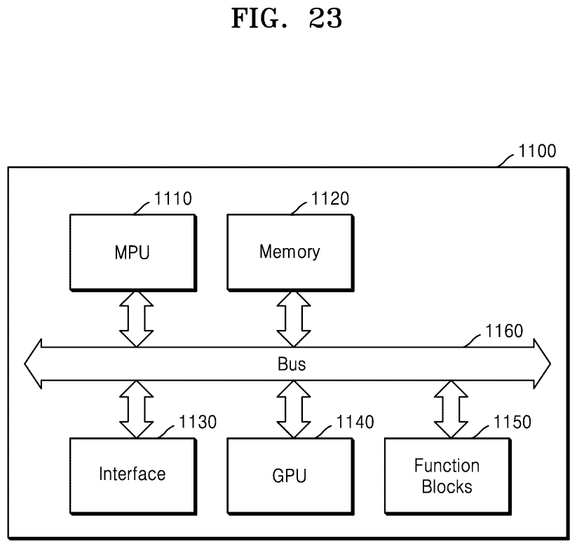

FIG. 23 is a block diagram schematically showing a configuration of a semiconductor package 1100 according to an example embodiment.

Specifically, the semiconductor package 1100 may include a micro processing unit (MPU) 1110, memory 1120, an interface 1130, a GPU 1140, function blocks 1150, and a bus 1160 for establishing connections therebetween. The semiconductor package 1100 may include both the MPU 1110 and the GPU 1140 but may include only one of the MPU 1110 and the GPU 1140.

The MPU 1110 may include a core and an L2 cache. For example, the MPU 1110 may include multi-cores. In the multi-cores, individual cores may have equal or different performance.

Also, in the multi-cores, the individual cores may be activated simultaneously or activated at different times from each other. The memory 1120 may store the results of processing performed in the function blocks 1150 under control by the MPU 1110.

For example, as contents stored in the L2 cache of the MPU 1110 are flushed, the contents may be stored in the memory 1120. The interface 1130 may interface with external devices. For example, the interface 1130 may interface with a camera, a liquid crystal display (LCD), and a speaker.

The GPU 1140 may perform graphics functions. For example, the GPU 1140 may perform video codec or may process 3D graphics. The function blocks 1150 may perform various functions. For example, when the semiconductor package 1100 includes an AP used in the mobile device, some of the function blocks 1150 may perform a communication function.

The semiconductor package 1100 may include any one of the semiconductor packages PK1 to PK4 according to the inventive concept described above. For example, the MPU 1110 and/or the GPU 1140 may include any one of the semiconductor packages PK1 to PK4 illustrated above.

The memory 1120 may include any one of the semiconductor packages PK1 to PK4 illustrated above. The interface 1130 and the function blocks 1150 may include any one of the semiconductor packages PK1 to PK4 illustrated above.

While the inventive concept has been particularly shown and described with reference to embodiments thereof, it will be understood that various changes in form and details may be made therein without departing from the spirit and scope of the following claims.

What is claimed is:

1. A semiconductor package comprising:
a printed circuit board; and
a semiconductor chip electrically connected to the printed circuit board,
wherein the printed circuit board comprises:
a plurality of chip connection pads; and
a plurality of signal correction patterns spaced apart from the plurality of chip connection pads,
wherein the semiconductor chip comprises a plurality of chip pads, and
wherein the printed circuit board further comprises thereon a board connection member configured to electrically connect the plurality of chip connection pads to the plurality of signal correction patterns to correct signal characteristics between the plurality of chip pads and the plurality of chip connection pads.

2. The semiconductor package of claim 1, wherein the plurality of signal correction patterns are spaced apart from each other and have different lengths.

3. The semiconductor package of claim 1, wherein the plurality of signal correction patterns are spaced apart from each other and have different lengths depending on operating frequencies of the semiconductor chip.

4. The semiconductor package of claim 1, wherein one end of each of the plurality of signal correction patterns is electrically connected to the board connection member, and the other end of each of the plurality of signal correction patterns is not electrically connected to the board connection member.

5. The semiconductor package of claim 1, wherein the plurality of chip pads comprise a plurality of low-speed signal chip pads and at least one high-speed signal chip pad.

6. The semiconductor package of claim 5, wherein the plurality of chip connection pads comprise a plurality of low-speed signal chip connection pads electrically connected to the plurality of low-speed signal chip pads and a high-speed signal chip connection pad electrically connected to the at least one high-speed signal chip pad.

7. The semiconductor package of claim 6, wherein the high-speed signal chip connection pad is electrically connected to at least one of the plurality of signal correction patterns via the board connection member.

8. The semiconductor package of claim 1, wherein the plurality of chip connection pads are arranged in a same plane as the plurality of signal correction patterns.

9. The semiconductor package of claim 1, wherein the board connection member comprises a bonding wire.

10. The semiconductor package of claim 1, wherein the board connection member comprises a board connection pattern.

11. The semiconductor package of claim 1, wherein the semiconductor chip comprises a logic chip or a memory chip.

12. A semiconductor package comprising:
a printed circuit board comprising signal correction patterns;
a semiconductor chip mounted on the printed circuit board;
a first signal line configured to electrically connect a first connection point on the printed circuit board to a second connection point on the semiconductor chip; and
a second signal line configured to electrically connect a third connection point on the signal correction patterns to the first connection point on the printed circuit board, the third connection point being spaced apart from the first and second connection points,
wherein a second length of the second signal line is greater than a first length of the first signal line to correct signal characteristics of the first signal line.

13. The semiconductor package of claim 12,
wherein the printed circuit board further comprises chip connection pads electrically connected to the semiconductor chip,
wherein the semiconductor chip further comprises chip pads,
wherein the first connection point is located on the chip connection pads, and
wherein the second connection point is located on the chip pads.

14. The semiconductor package of claim 13, wherein the first signal line comprises a chip connection member configured to connect the chip connection pads to the chip pads.

15. The semiconductor package of claim 13,
wherein the printed circuit board further comprises at least one board connection member configured to connect the chip connection pads to one end of the signal correction patterns, and
wherein the second signal line comprises the board connection member and the signal correction patterns.

16. The semiconductor package of claim 15,
wherein the signal correction patterns are spaced apart from each other,
wherein the other ends of the signal correction patterns are not electrically connected to the at least one board connection member,
wherein the second length is determined by lengths of the signal correction patterns, and
wherein the lengths of the signal correction patterns are different from each other depending on operating frequencies of the semiconductor chip.

17. A semiconductor package comprising:
a printed circuit board; and
a semiconductor chip mounted on the printed circuit board and electrically connected to the printed circuit board via a connection member,
wherein the printed circuit board comprises:
a plurality of chip connection pads arranged on a board base, wherein the plurality of chip connection pads comprise a plurality of low-speed signal chip connection pads and at least one high-speed signal chip connection pad; and
a signal correction unit spaced apart from the plurality of chip connection pads on the board base, wherein the signal correction unit comprises a plurality of signal correction patterns spaced apart from each other, and
wherein the semiconductor chip comprises a plurality of chip pads, wherein the plurality of chip pads comprise a plurality of low-speed signal chip pads and at least one high-speed signal chip pad, and
wherein the connection member comprises:
chip connection members configured to electrically connect the plurality of chip pads to the plurality of chip connection pads, wherein the chip connection members comprise a plurality of low-speed signal chip connection members configured to electrically connect the plurality of low-speed signal chip pads to the plurality of low-speed signal chip connection pads and a high-speed signal chip connection member configured to connect the at least one high-speed signal chip pad to the at least one high-speed signal chip connection pad; and
a board connection member configured to electrically connect the at least one high-speed signal chip connection pad to at least one of the plurality of signal correction patterns.

18. The semiconductor package of claim 17, wherein the plurality of signal correction patterns are spaced apart from each other and have different lengths depending on operating frequencies of the semiconductor chip.

19. The semiconductor package of claim 17, wherein the plurality of chip connection pads are arranged in a same plane as the plurality of signal correction patterns.

20. The semiconductor package of claim 17, wherein the board connection member comprises a bonding wire or a board connection pattern.
